(19) United States
(12) Patent Application Publication
(10) Pub. No.: US 2011/0256730 A1
(43) Pub. Date: Oct. 20, 2011

(54) FINISHING METHOD FOR MANUFACTURING SUBSTRATES IN THE FIELD OF ELECTRONICS

(75) Inventor: Gregory Riou, Crolles (FR)

(73) Assignee: S.O.I. Tec Silicon on Insulator Technologies, Bernin (FR)

(21) Appl. No.: 13/141,033

(22) PCT Filed: Mar. 10, 2010
(86) PCT No.: PCT/EP2010/053050

§ 371 Date: Jun. 20, 2011

(30) Foreign Application Priority Data
Mar. 17, 2009 (FR) 0951690

(51) Int. Cl. H01L 21/302

(52) U.S. Cl. 438/759; 257/E21.214

(57) ABSTRACT

The invention relates to a method for finishing the surface of semiconducting substrate that has a set of layers and a useful semiconducting layer on at least one of the faces of the substrate, wherein the useful layer has a rough free surface. The method smoothes out the rough free surface of the useful layer by creating a protective layer covering the surface of the useful layer with a thickness 1 to 3 times larger than the peak-to-valley distance of the surface of the useful layer, at least one polishing-oxidation sequence that includes the successive steps of polishing the surface of the protective layer, with the polishing being adjusted so as not to attack the useful layer, and performing a thermal oxidation with supply of oxygen gas of the substrate in order to transform a portion of the useful layer into an oxide layer and reduce the roughness of the surface of the useful layer.

### FIELD OF THE INVENTION

The invention relates to a method for finishing the surface of semiconducting substrates intended for applications in microelectronics and/or optoelectronics. The invention notably relates to the making of substrates of the Semiconductor on Insulator (SeOI) type.

### PRESENTATION OF THE PRIOR ART

SeOI substrates are currently used in the electronics industry. They include for example Silicon on Insulator (SOI) or Germanium on Insulator (GeOI).

The manufacturing of SeOI substrates may resort to various methods, notably methods involving the creation of a weakening area in the thickness of an initial substrate, a so-called donor substrate, and a fracture at this area, after assembling the donor substrate with a receiving substrate. This SeOI type thus comprises at least two layers, one from the donor substrate, the other one from the receiving substrate.

The Smart Cut™ method is a known example of such a method. In particular, details may be found on this type of method in a great number of documents already published, such as for example the excerpt from pages 50 and 51 of the textbook “Silicon-on-Insulator technology: material tools VLSI, second edition” of Jean-Pierre Colinge at “Kluwer Academic Publishers”.

The methods for manufacturing SeOI notably allow a useful layer (such as for example silicon) to be obtained on one of the faces of a substrate, said useful layer having a free surface. By “free surface” is meant the surface of a layer of the substrate which is exposed to the outside environment (as opposed to an interface surface which is in contact with the surface of another layer or of another element).

Before the finishing steps, the free surface of the useful layer is not generally perfectly smooth and has some roughness. This roughness of the free surface is notably due to certain steps of the manufacturing method. The manufacturing steps may for example be the step of fracture of the donor substrate. This may also be the growth of a buffer layer on a face of the receiving substrate, said buffer layer being for example a silicon-germanium (SiGe) layer. It is then necessary to smooth the free surface of the substrate, which is accomplished in said finishing steps.

Roughness is generally expressed by an average quadratic value, a so-called RMS (Root Mean Square) value, or by a so-called PSD (Power Spectral Density). As an example, it is current to find roughness specifications which should not exceed 5 angstroms in RMS value.

The roughness measurements may be carried out by means of an atomic force microscope (AFM). With this type of apparatus, the roughness is measured on surfaces scanned by the tip of the AFM microscope, ranging from 1×1 μm² to 10×10 μm² and more seldomly 50×50 μm², or even 100×100 μm². Generally, the roughness is said to be “high frequency” or “low frequency” roughness. So-called high frequency roughness corresponds to scanned surfaces of small dimensions (of the order of 1×1 μm²). So-called low frequency roughness corresponds to scanned surfaces of larger dimensions (of the order of 10×10 μm² or more).

The finishing step for manufacturing SeOIs, consisting of smoothing the free surface of the SeOI substrates in order to erase the roughnesses defined earlier, may notably resort to methods such as chemical mechanical polishing (CMP) or the smoothing process by rapid thermal annealing (RTA). CMP and RTA may also be combined.

CMP is a polishing method combining mechanical friction and chemical action. In particular, the principle of CMP is to transform by a chemical action the surface which is intended to be polished, and to then remove this transformed surface by mechanical abrasion.

A drawback of CMP is that the chemical action is directly exerted on the free surface, which may have detrimental effects on said free surface, such as for example the creation of holes in a germanium surface.

Another drawback of CMP is that it may cause thickness inhomogeneity of the useful layer of the substrate.

From document KR 2000 0060787, for example and as schematized in FIGS. 6-8, a finishing method is known for smoothing the free surface of a substrate 1 comprising a useful silicon layer 4, said method comprising a step of creating an oxide layer 32 covering the silicon layer 4, a step of CMP polishing said oxide layer 32 and a second step of oxidation of the substrate 1, the goal of which is to ensure smoothing of the surface 34 of the silicon layer 4.

The surface 34 of the silicon layer 4 to be smoothed comprises peaks (height maxima) and valleys (height minima).

In this method, the oxide layer 32 is created with a high thickness, comprised between 1 μm and 5 μm, covering the useful layer 4.

Given that the thickness inhomogeneity induced by CMP polishing increases with the thickness of the layer to be polished, it emerges that upon completion of CMP polishing of the oxide layer having a high thickness comprised between 1 μm and 5 μm, the surface 33 of the polished oxide layer 32, schematized in FIG. 7, has an important inhomogeneity, i.e. a low frequency thickness variation.

In this method, the polished oxide layer 32 obtained upon completion of the polishing step, is therefore characterized by strongly inhomogeneous thickness caused by the action of CMP polishing.

Therefore, certain peaks of the surface 34 of the silicon layer 4 are closer to the surface 33 of the oxide layer 32 than other ones.

This implies that during the following step of second oxidation of the substrate 1, the peaks which are the closest to the surface 21 are more oxidized than the other peaks, as illustrated in FIG. 8.

Finally, the smoothing of the surface 34 of the useful layer 4 is therefore imperfect. With this method, it is therefore not possible to obtain low roughness over the whole surface 34 of the useful layer 4.

Moreover, RTA consists of annealing under a reducing atmosphere, for example containing hydrogen, the SeOI substrate in order to smooth the free surface.

A drawback of RTA is that it essentially acts on the surface roughnesses with high spatial frequency, in particular less than or equal to 10×10 μm².

Another further drawback is that RTA is conducted at high temperature, i.e. at a temperature generally above 1,000° C. Therefore, RTA cannot be used for useful layers including germanium (Ge), because this element liquefies at 930° C.

### PRESENTATION OF THE INVENTION

The invention proposes an alternative to the aforementioned smoothing methods, in order to overcome at least one of the aforementioned drawbacks.

For this purpose, a method for finishing the surface of a semiconducting substrate is proposed according to the invention, said substrate comprising a set of layers comprising a useful semiconductor layer on at least one of the faces of said substrate, said useful layer comprising a rough free surface, said method being suitable for smoothing the free surface, said method being characterized in that it comprises the successive steps:
creating a protective layer covering the surface of the useful layer with a thickness 1 to 3 times larger than the peak-to-valley distance of said surface of the useful layer,
at least one polishing-oxidation sequence, said sequence comprising the successive steps:

polishing the surface of the protective layer, said polishing being adjusted so as not to attack the useful layer, and

performing a thermal oxidation with supply of oxygen gas of the substrate in order to transform a portion of the useful layer into an oxide layer, in order to reduce the roughness of the surface of the useful layer.

The invention is advantageously completed by the following features, taken alone or in any of their technically possible combinations:
the protective layer is an oxide or nitride layer;
polishing of the surface of the protective layer is selective polishing, capable of selectively polishing the protective layer without attacking the useful layer;
creation of an oxide or nitride layer covering the surface of the useful layer includes deposition of nitride or oxide;
deposition of nitride or oxide is accomplished by PECVD or LPCVD;
creation of an oxide or nitride layer covering the surface of the useful layer includes dry or wet thermal oxidation with supply of oxygen gas or thermal nitridation with supply of nitrogen gas;
thermal oxidation of the substrate is a dry or wet oxidation;
the polishing step is a non-selective polishing step;
a protective layer is created, covering the surface of the useful layer with a thickness 1.8 times larger than the peak-to-valley distance of the surface of the useful layer;
creation of an oxide layer covering the surface of the useful layer forms the oxide layer with a thickness from 1 to 3 times or 1.8 times larger than the peak-to-valley distance of the surface of the useful layer;
the useful layer is germanium, and the creation of a germanium oxide layer as a protective layer covering the surface of the useful layer, is accomplished by thermal oxidation with supply of oxygen at a temperature comprised between 450 and 550° C., and the polishing is non-aqueous polishing notably of the CMP type, or dry polishing;
the useful layer includes silicon, and the creation of a silicon oxide layer as a protective layer covering the surface of the useful layer, is accomplished by thermal oxidation with supply of oxygen at a temperature of less than 600° C.

An advantage of the invention is to propose a finishing method which avoids the risk of damaging the free surface of the useful layer of the substrate.

Another advantage of the invention is to propose a finishing method which is applied at low temperature.

Another further advantage of the invention is to describe a finishing method which yield reduced roughness at high and low frequencies.

Finally, another advantage of the invention is to propose a finishing method which may be used even in the case of a useful layer in germanium.

### PRESENTATION OF THE FIGURES

Other characteristics and advantages of the invention will further become apparent from the following description which is purely illustrative and non-limiting and should be read with reference to the appended drawings wherein:

FIG. 1 is a schematic illustration of a semiconductor substrate to be treated with the finishing product according to the invention;

FIG. 2 is a schematic illustration of a semiconductor substrate after creating an oxide or nitride layer;

FIG. 3 is a schematic illustration of a semiconductor substrate after a selective polishing step;

FIG. 4 is a schematic illustration of a semiconductor substrate after a non-selective polishing step;

FIG. 5 is a schematic illustration of a semiconductor substrate after an oxidation step;

FIGS. 6-8 are an illustration of various steps of a finishing method according to the prior art.

### DETAILED DESCRIPTION

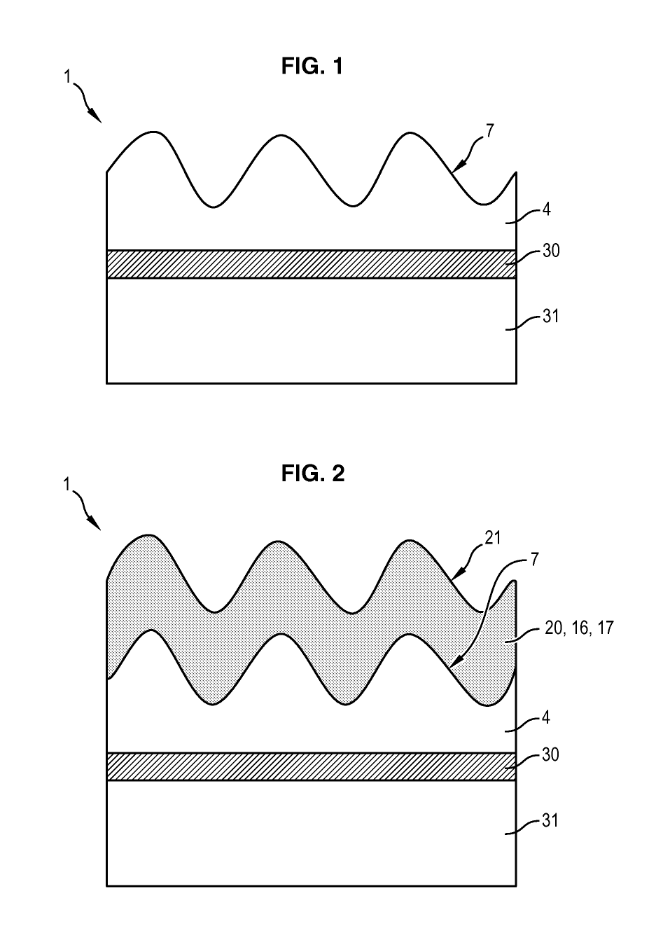

In FIG. 1, a semiconductor substrate 1 is illustrated. The substrate 1 comprises a useful semiconductor layer 4 on at least one of its faces. This is for example a silicon (Si) or germanium (Ge) layer.

The semiconductor substrate 1 comprises a set of superposed layers. In the case of a substrate 1 of the Semiconductor-On-Insulator (SeOI) type, the layer 30 is generally an electric insulator layer, such as an oxide layer, and the layer 31 is a semiconductor supporting layer.

As this is illustrated schematically and with exaggerated amplitude in FIG. 1, the useful layer 4 comprises a rough free surface 7. In the case of a substrate obtained by transfer, the roughness is in majority caused by the fracture step preceding the obtaining of the substrate 1. As an indication, the roughness of the free surface 7 after fracture, is typically of 50-100 angstroms as an RMS value at high frequencies (scanned surface, 1×1 μm²), and within the same interval at low frequencies (scanned surface 10×10 μm²). The roughness after fracture is very high and is significantly difficult to measure with an ATM microscope.

The method according to the invention notably aims at smoothing the rough free surface 7, i.e. minimizing its roughness, in order to obtain a substrate 1 with a useful layer 4, the quality of which is sufficient and compatible with the use of this useful layer 4 in applications in micro- and/or opto-electronics.

The first step of the method includes the creation of a protective layer 20 covering the rough free surface 7 of the useful layer 4, as this may be seen in FIG. 2, wherein the protective layer 20 covers the useful layer 4 and includes a surface 21, which is free.

As the protective layer 20 covers the useful layer 4 of the substrate 1, said protective layer 20 notably provides protection of said useful layer 4, and this during a subsequent polishing step of the method according to the invention, which will be described subsequently.

In particular, during said polishing step, with the protective layer 20, it is possible to prevent the mechanical polishing interaction which may exist between the polishing tissue and the useful layer 4, from damaging said useful layer 4.

Also, in the case when the polishing tissue comprises a chemical substance (also designated by “slurry”) containing chemicals capable of exerting chemical action on the useful layer 4, the presence of the protective layer 20 covering the useful layer 4 prevents the chemicals from damaging said useful layer 4.

Moreover, as this will be seen subsequently, the protective layer 20, once it has been polished, fulfils an additional function during a step of thermal oxidation of the substrate 1, which is a step following the polishing step. In this oxidation step, the fact that the protective layer 20 covers the useful layer 4 will allow the areas of the surface 7 of the useful layer 4 corresponding to height maxima (“peaks”) to be more oxidized than the areas corresponding to height minima (“valleys”), and this because of their proximity to the surface of the substrate 1, i.e. the surface 21 of the protective layer 20 which will finally allow smoothing of said surface 7.

Advantageously, the protective layer 20 is an oxide 16 or nitride 17 layer.

The techniques for creating an oxide 16 or nitride 17 layer as a protective layer 20 covering the rough free surface 7 of the useful layer 4 notably include deposition of oxide or of nitride, and thermal oxidation or nitridation.

The oxide or nitride deposition technique consists of depositing an oxide or nitride film over the rough free surface 7 of the useful layer 4. The PECVD (Plasma Enhanced Chemical Vapor Deposition) or LPCVD (Low Pressure Chemical Vapor Deposition) methods are notably used but not as a limitation.

With the PECVD method, it is possible to deposit films at relatively low temperature: 250-350° C. for an oxide deposit, such as for example SiO₂, and 380-400° C. for a nitride deposit such as for example Si₃N₄.

The advantage of low temperature deposition is to preserve the heat balance, i.e. minimize the temperature and duration of the treatment applied to the materials of the layers of the substrate 1. By low temperature deposition is meant a deposit produced at a temperature of substantially less than 500° C. In the case when a nitride layer 17 covering the surface 7 of a useful layer 4 including germanium (Ge) is created, it is preferable to create said nitride layer 17 by depositing nitride, since germanium is sensitive to high temperatures.

If the heat balance of the materials of the layers of the substrate 1 does not have to be absolutely preserved, it is possible to use deposition by the LPCVD method. This technique consists of producing low pressure chemical phase deposition. This deposition is normally carried out in an oven with a hot wall at temperatures of the order of 500-600° C.

As stated earlier, the creation of an oxide 16 or nitride 17 layer covering the rough free surface 7 of the useful layer 4 may also be carried out by thermal oxidation or nitridation.

Thermal oxidation or nitridation consists of placing the substrate 1 in an atmosphere notably including oxygen or nitrogen gas, and of heating it to a temperature notably selected according to the material of the useful layer 4.

Thermal oxidation of the substrate 1 may be a dry or wet thermal oxidation. Dry oxidation is for example conducted by heating the substrate 1 under oxygen gas. Wet oxidation is for example conducted by heating the substrate 1 in an atmosphere of mixed oxygen and hydrogen gas, oxygen being in excess, which allows the atmosphere to be loaded with steam.

In dry or wet oxidation, according to standard methods known to the person skilled in the art, the oxidation atmosphere may also be loaded with hydrochloric acid.

In the case of a useful layer 4 including silicon, it is advantageous to proceed with wet thermal oxidation. The oxidation may be conducted at a temperature of less than 600° C.

In the case of a useful layer 4 including germanium, it is advantageous to proceed with thermal oxidation in an oxygen atmosphere, the oxygen concentration of which is from diluted to pure. Oxidation of the useful layer 4 including germanium may be thermal oxidation, which can be either dry or wet oxidation.

By a diluted oxygen atmosphere is meant an atmosphere containing oxygen gas diluted with another gas. In the case of dry thermal oxidation, the oxygen may for example be diluted in argon (Ar) or in dinitrogen (N₂).

In the case of germanium, the oxidation may be conducted at a temperature comprised between 450 and 550° C.

Moreover, in the case when the useful layer 4 comprises SiGe, thermal oxidation of the substrate 1 is accompanied, as this is known to the person skilled in the art, by a phenomenon of condensation of the germanium in depth, i.e. a transformation of the useful layer 4 into a layer of quasi-pure germanium, and by creation of a layer 16 of silicon oxide (SiO₂) covering said useful germanium layer 4.

Nitridation may be carried out by heating the substrate in a nitrogen gas atmosphere at temperatures comprised between 600° C. and 900° C. for example.

Thus, the method according to the invention applies oxidation or nitridation at temperatures of less than 900° C., i.e. at a low temperature relatively to the methods of the prior art. This is particularly advantageous, notably in the case when it is proceeded with oxidation of a useful layer 4 comprising germanium, because germanium liquefies at about 930° C.

It is possible to create the protective layer 20 (and therefore the oxide 16 or nitride 17 layer for example) so that said protective layer 20 has topology and roughness compliant with the initial topology and roughness of the useful layer 4 which it covers. In this case, the surface 21 of the protective layer 20 has a roughness substantially identical with the initial roughness of the surface 7 of the useful layer 4.

The continuation of the method according to the invention consists of performing at least a polishing-oxidation sequence, i.e. comprising a polishing step followed by an oxidation step. This sequence may be repeated iteratively, as this will be explained in the following.

The polishing of the protective layer 20 should be adjusted so as not to attack the useful layer 4, in order not to damage said useful layer 4.

By attack of a material layer by a polishing method, is meant removal of material from said layer by at least 50 angstroms. Below this threshold, it will be considered that the relevant layer is not attacked.

Advantageously, selective polishing capable of selectively polishing the protection layer 20 without attacking the useful layer 4 is used. With selective polishing it is possible to polish the protective layer 20 preferentially at the useful layer 4. In this type of polishing, it is the protection layer 20 which is polished, the useful layer 4, as for it, is preserved. The advantage of such polishing is that the interaction which may exist between the polishing tissue and the useful layer 4 is negligible and does not lead to the attack of said useful layer 4. For example, in some selective polishing methods, material removal from the useful layer 4 is less than 20 angstroms.

The selective polishing technique is well known to the person skilled in the art. The selectivity of polishing is defined by the ratio(s) (R) of the polishing rates of two or several different materials under identical polishing conditions. Selective polishing is characterized by a high ratio R (or low ratio, depending on the choice of the direction of the quotient), for example comprised between 10 and 200. Non-selective polishing is characterized by a ratio R close to the value of 1, typically from 1 to 6, the polishing rates being approximately equivalent for the different relevant materials. Selective polishing may be polishing of the mechanical or mechano-chemical type, such as CMP.

The risk of damaging the useful layer 4 is zero, given that selective polishing will only attack the protection layer 20. Unlike non-selective polishings, it is possible to polish the surface 21 of the protection layer 20 until the peaks 29 of the surface of the useful layer 4 begin to become exposed. By peaks, are meant areas of the surface 7 corresponding to height maxima.

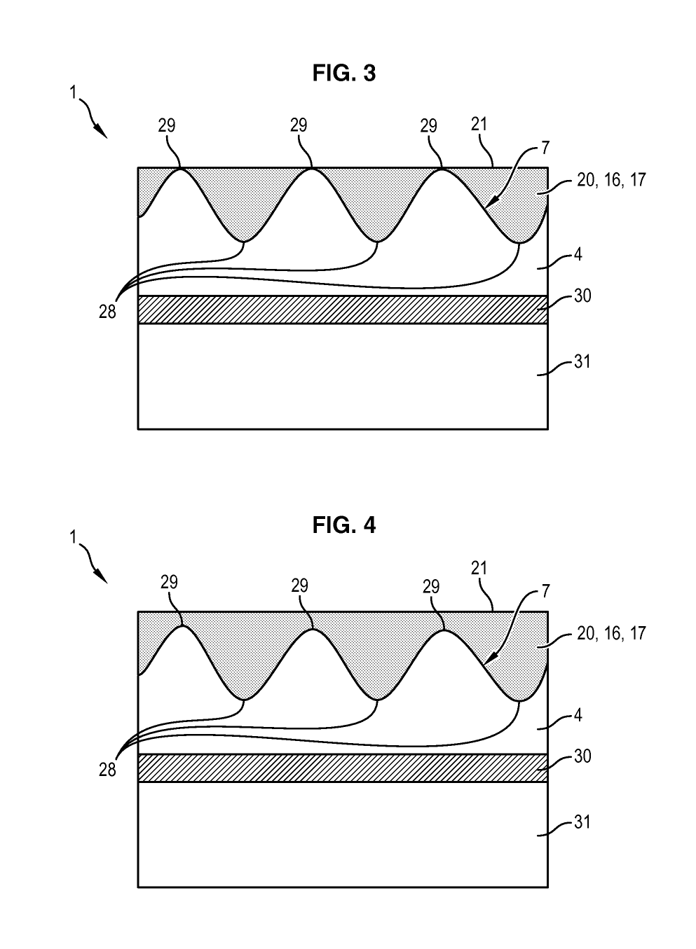

At this stage, it is advantageously possible to carry on with applying selective polishing, since selective polishing does not attack the material of the useful layer 4. Further, this polishing does not attack either the material of the protective layer 20 present in the valleys 28 of the surface 7 of the useful layer 4, such as for example oxide or nitride, since the polishing tissue cannot reach them because of the persisting peaks 29. By valleys 28 are meant areas of the surface 7 corresponding to height minima. A diagram of the substrate 1 after applying selective polishing is illustrated in FIG. 3.

If non-selective polishing is used, such as for example non-selective CMP polishing or non-selective dry polishing, the surface 21 of the protective layer 20 has to be polished so as not to expose the useful layer 4, in order not to attack said useful layer 4. Therefore the surface 21 of the protective layer 20 advantageously has to be polished so as to leave a fine layer of material of the protective layer 20 over the useful layer 4. In the case when the protective layer 20 is an oxide 16 or nitride 17 layer, the question is therefore to leave a fine layer of oxide or nitride above the useful layer 4.

A diagram of the substrate 1 after applying a non-selective polishing is illustrated in FIG. 4.

The use of selective polishing has certain advantages. It is known that any polishing has a certain resolution, i.e. that any polishing reduces the height of a layer of a given material by a minimum height. The resolution of the polishing, defined relatively to a given material, will therefore be the minimum height of material which the polishing removes from a layer of a given material.

If non-selective polishing is used in the polishing-oxidation sequence, it is preferable to have a protective layer 20 with a height at least greater than or equal to the resolution of the non-selective polishing. In the opposite case, the non-selective polishing will necessarily attack the useful layer 4, which is not desirable.

The advantage of selective polishing is that it allows an interruption at the peaks 29 of the surface 7 of the useful layer 4 without being limited by the resolution of the polishing method used. Indeed, selective polishing does not attack a useful layer 4.

Also, it is obvious that there exists a desirable maximum height for the protective layer 20 created in the prior step for creating a protective layer 20. Indeed, it is unnecessary to create a too thick protective layer 20 since the latter will be polished in the polishing step which follows the step for creating the protective layer 20.

Advantageously, the step for creating a protective layer 20 covering the surface 7 of the useful layer 4 forms the protective layer 20 with a thickness 1-3 times larger than the peak-to-valley distance from peaks 29 to valleys 28 of the rough free surface 7 of the useful layer 4, or with a thickness 1.8 times larger than the peak-to-valley distance from peaks 29 to valleys 28 of the rough free surface 7 of the useful layer 4. It is recalled that the peak-to-valley distance from peaks 29 to valleys 28 is defined as the maximum of all the heights separating the peaks 29 from the valleys 28.

The thickness at least once (or 1.8 times) equal to the peak-to-valley distance of the rough free surface 7 of the useful layer 4 corresponds to the resolution of a CMP polishing, at the filing date of the invention. It is possible that these values may change with the development of the resolution of CMP type polishing techniques.

By means of this small thickness of the protective layer 20, polishing applied in the following step, for example of the CMP type, is prevented from causing inhomogeneity in the thickness of the polished protective layer 20.

If the useful layer 4 is germanium, and if at the previous step of the method a protective layer 20 is created, being a layer 16 of germanium oxide covering the useful layer 4, either non-aqueous polishing has to be used, which means for the person skilled in the art polishing using an organic solvent, or dry polishing has to be used, i.e. without any solvent, and therefore essentially based on mechanical polishing action. Indeed, germanium oxide is soluble in an aqueous medium and risks dissolution if polishing is used, which uses a solution comprising water, this is why non-aqueous polishing or dry polishing are polishing methods adapted to this exemplary embodiment.

In the case of non-aqueous polishing, i.e. a polishing using an organic solvent, mechano-chemical polishing such as CMP may advantageously be applied, which uses, in addition to the organic solvent, a chemical substance (also designated as “slurry”) containing chemicals capable of exerting chemical action for transforming the layer to be polished, said chemicals being well-known to the person skilled in the art.

The polishing-oxidation sequence step following polishing is a thermal oxidation step of the substrate 1, with supply of oxygen. The thermal oxidation consists of placing the substrate 1 in an atmosphere notably including oxygen gas, and of heating it to a temperature selected according to the material of the useful layer 4. This oxidation may be a dry or wet thermal oxidation. The operating conditions of this thermal oxidation are of the same kind as those described earlier during the thermal oxidation of the substrate 1 for creating an oxide layer 16 as a protective layer 20 covering the rough free surface 7 of the useful layer 4.

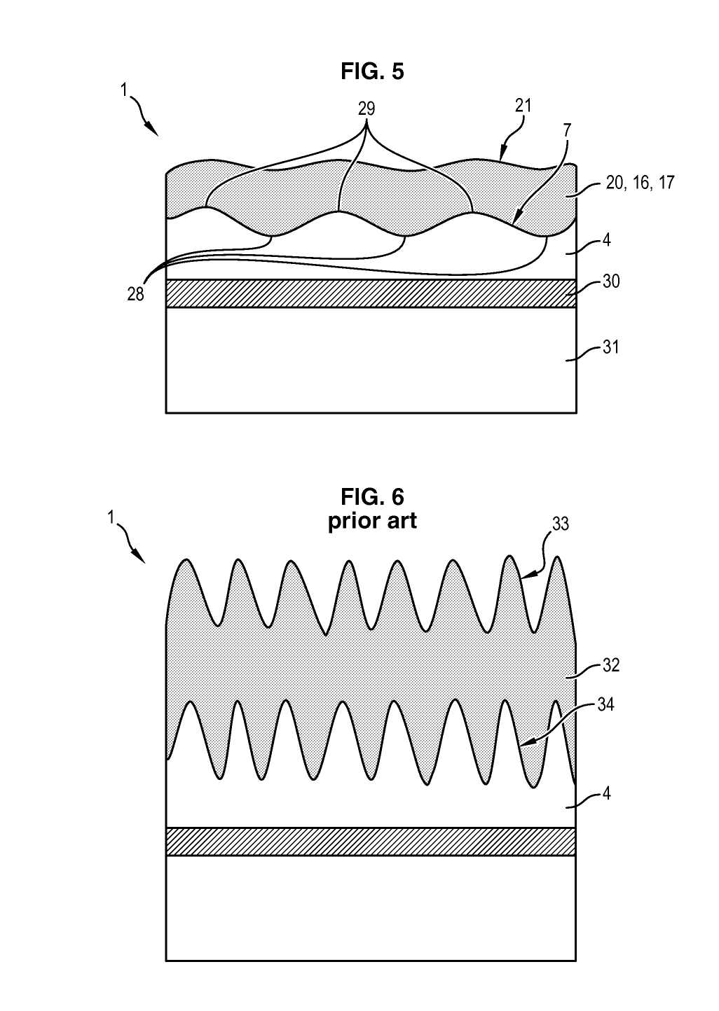

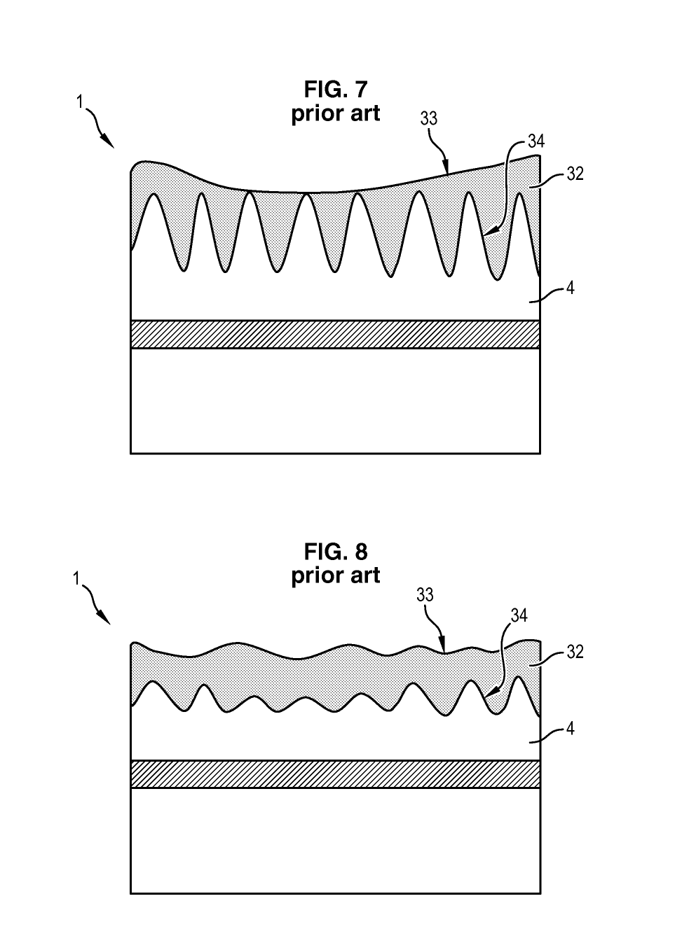

A goal of thermal oxidation of the substrate 1 is to transform a portion of the useful layer 4 into an oxide layer 16, in order to reduce the roughness of the surface 7 of the useful layer 4. In this oxidation, the material of the peaks 29 of the surface 7 of the useful layer 4 will be more consumed by oxidation than that of the valleys 28 of the surface 7, since the peaks 29 are much closer to the surface of the substrate 1, i.e. to the surface 21 of the protective layer 20, than the valleys 28, located much farther in depth. The effect of thermal oxidation on the substrate 1 is illustrated in FIG. 5.

In the case when the creation of a nitride layer 17 as a protective layer 20 has been applied at the beginning of the method, the effect of the thermal oxidation, i.e. strong oxidation of the peaks 29 and low oxidation of the valleys 28, is more pronounced. Indeed, the creation of a nitride layer 17 at the beginning of the method notably has the advantage of further blocking the diffusion of oxygen towards the valleys 28 during thermal oxidation, than accomplished by the oxide layer 16.

At this stage of the method, the roughness of the surface 7 of the active layer 4 of the substrate 1 is reduced in high and low frequencies relatively to its initial roughness, i.e. relatively to its roughness before applying the method according to the invention.

In order to be able to further smooth the surface 7 of the active layer 4, the polishing-oxidation sequence may be reiterated as many times as required. During the gradual iterations of the polishing-oxidation sequence, the peaks 29 and the valleys 28 of the surface 7 of the useful layer 4 will be completely smoothed out, by which a useful layer 4 may be obtained with strongly reduced roughness.

At the end of the method, it is possible to clean the protective layer 20 with any type of method known to the person skilled in the art.

With the method according to the invention, it is possible to act on the high and low frequency roughnesses and to reduce said roughnesses.

The method according to the invention may advantageously be used for removing the “cross-hatch”, which is a defect occurring for example on the useful layer 4 of relaxed SiGe, and well known to the person skilled in the art. This defect forms at the surface of the useful layer and forms a well ordered network of microgrooves giving to the surface the aspect of a checkerboard, called “cross-hatch” in the art.

Moreover, the method according to the invention advantageously applies to the reuse (also designated as “refresh”) of the plates (also designated as “wafers”) of silicon used in the manufacturing methods of SeOIs, such as the Smart Cut™ method. Indeed, in these methods, a donor semiconducting substrate and a receiver semiconducting substrate are adhesively bonded, said receiver semiconducting substrate comprising an insulator layer. After implanting ions generating a weakening area and fracture around this area, an SeOI is obtained on one side and a semiconductor substrate on the other which may be reused. In order to be able to reuse the semiconducting substrate stemming from the fracture, it should be proceeded with finishing operations. The method according to the invention is advantageously applied and allows the semiconductor substrate to be smoothed out, which may then be reused in a subsequent method of the Smart Cut™ type.

Finally, the method according to the invention may advantageously be used in the case when the useful layer 4 of the substrate 1 comprises a semiconductor material of the III-V type, i.e. a composite semiconductor made from one or more elements from column III of the periodic table of the elements and from one or more elements of column V.

1.-12. (canceled)

13. A method for finishing the surface of a semiconductor substrate having top and bottom faces and comprising a set of layers with a useful semiconductor layer on at least one of the faces, wherein the useful layer has a rough surface, which method comprises smoothing out the rough surface of the useful layer by:
creating a protective layer covering the rough surface of the useful layer with the protective layer having a thickness that is 1 to 3 times larger than the peak-to-valley distance profile of the rough surface of the useful layer; and
conducting at least one polishing-oxidation sequence which comprises:
polishing the protective layer without attacking the useful layer, and
performing a thermal oxidation with oxygen in order to transform a portion of the useful layer into an oxide layer to thus reduce the roughness of the surface of the useful layer.

14. The method according to claim 13, wherein the protective layer comprises an oxide.

15. The method according to claim 14, wherein the oxide is deposited by PECVD (Plasma Enhanced Chemical Vapor Deposition) or LPCVD (Low Pressure Chemical Vapor Deposition).

16. The method according to claim 14, wherein the oxide is provided by thermal oxidation with oxygen.

17. The method according to claim 13, wherein the protective layer comprises a nitride.

18. The method according to claim 17, wherein the nitride is deposited by PECVD (Plasma Enhanced Chemical Vapor Deposition) or LPCVD (Low Pressure Chemical Vapor Deposition).

19. The method according to claim 17, wherein the nitride is provided by thermal nitridation with nitrogen.

20. The method according to claim 13, wherein the polishing is a selective polishing of only the protective layer such that the peaks of the useful layer can be exposed.

21. The method according to claim 13, wherein the polishing is a non-selective polishing conducted in a manner so as to only remove part of the protective layer without exposing the useful layer.

22. The method according to claim 13, wherein the protective layer is formed at a thickness that is about 1.8 times larger than the peak-to-valley distance of the rough surface of the useful layer.

23. The method according to claim 13, wherein the useful layer comprises silicon or germanium.

24. The method according to claim 13, wherein the useful layer comprises germanium, and oxide layer is a germanium oxide layer formed by thermal oxidation of the useful layer at a temperature between 450 and 550° C.

25. The method according to claim 24, wherein the polishing is non-aqueous polishing or dry polishing.

26. The method according to claim 13, wherein the useful layer comprises silicon, and the oxide layer is a silicon oxide layer formed by wet thermal oxidation at a temperature of less than 600° C.
